(19) United States
(12) Patent Application Publication
(10) Pub. No.: US 2023/0317443 A1
(43) Pub. Date: Oct. 5, 2023

(54) COMPOSITE SEMICONDUCTOR WAFER/CHIP FOR ADVANCED ICS AND ADVANCED IC PACKAGES AND THE MANUFACTURE METHOD THEREOF

(71) Applicants: nD-HI Technologies Lab,Inc., Taipei City (TW); ETRON TECHNOLOGY, INC., Hsinchu (TW)

(72) Inventors: Ho-Ming TONG, Taipei City (TW); Wei YEN, Taipei City (TW); Chao-Chun LU, Hsinchu (TW)

(73) Assignees: nD-HI Technologies Lab,Inc., Taipei City (TW); ETRON TECHNOLOGY, INC., Hsinchu (TW)

(21) Appl. No.: 17/854,489

(22) Filed: Jun. 30, 2022

Related U.S. Application Data
(60) Provisional application No. 63/324,655, filed on Mar. 29, 2022.

(51) Int. Cl. H01L 21/02; H01L 23/373; H01L 25/065; H01L 25/18

(52) U.S. Cl. CPC H01L 21/02002; H01L 23/3735; H01L 25/0657; H01L 25/18; H01L 25/0652; H01L 2225/06589; H01L 24/16

(57) ABSTRACT

The present invention discloses a method to form a composite semiconductor wafer with a first dimension. The method comprises: attaching a set of thermal dissipation layers to a temporary carrier; bonding the temporary carrier with the set of thermal dissipation layers to a semiconductor substrate with the first dimension, such that the set of thermal dissipation layers are bonded to the semiconductor substrate; and removing the temporary carrier to form composite semiconductor wafer with the first dimension.

This application claims the benefit of U.S. provisional application Ser. No. 63/324,655, filed on Mar. 29, 2022, the subject matter of which is incorporated herein by reference.

### BACKGROUND

### Technical Field

The disclosure relates to a semiconductor wafer, and more particularly to a semiconductor-diamond bi-wafer for the fabrication advanced ICs (integrated circuits) and advanced IC packages.

### Description of Background

The advent of 5G and AI has spurred a plethora of new end use applications in 3C, namely, data centers (i.e, cloud), base stations (i.e., connectivity) and commercial/edge electronics (i.e., client/edge), leading to high semiconductor growth and an exponential growth in data communication.

Semiconductor devices that target the high-performance computing (HPC) and data center markets have always represented the prevalent state-of-the-art, advanced ICs and state-of-the-art, advanced IC packaging technologies covering advanced system-in-a-packages (SiPs) such as 2.5D IC, 3D IC, fan-out, silicon photonics and chiplets-in-SiP.

Shown in FIG. 8 is a diagram of the conventional 2.5D IC package, wherein a plurality of high bandwidth memory (HBM) DRAM die 81 are mounted on a base die 82 which could be a memory controller, and the base die 82 together with other logic ICs 83 (such as central processing unit (CPU), graphics processing unit (GPU), field-programmable array (FPGA), etc.) are disposed on a silicon interposer 84 which is positioned on a laminate substrate 85. The silicon interposer 84 includes numerous through silicon vias (TSV) for intercommunicating signals among the HMB DRAM die 81, base die 82, logic ICs 83 and the laminate substrate 85. Heat dissipation is carried out through heat spreader, thermal interface material and heat sink which are typically bonded to the backside of the logic ICs 83. This is because the organic laminate substrate is a poor heat conductor.

The skyrocketing data traffic demands advanced ICs, particularly processors and even memories, and advanced SiP technologies in the extreme for HPC, data centers and even other high-end applications such as artificial intelligence (AI), 5G/6F RF/mmWave. All ICs generate heat when power is applied to them, not to mention, the astonishing amount of heat generated by processors nowadays. In order to achieve ever-higher performance to process the exponential increase in data traffic, processor chip power at data centers is expected to grow, reaching 1000 W per chip with chips packaged in 2.5D IC, 3D IC and/or chiplets-in-SiP platforms. The average rack power density for servers is currently around 7-16 k W. With HPC, power densities can reach 100 k W per rack. To maintain the device's operating junction temperature below the maximum allowed, effective heat flow from the IC through the package to the ambient is critical. Heat is the single biggest cause of failure in electronics. Statistically, reducing the operating junction temperature by 10° C. can double a device's lifetime. Regardless of the advanced IC nodes (involving silicon (Si), silicon carbide (SiC) or gallium nitride (GaN)) and advanced SiPs deployed, data centers are maxing out on how much heat they can dissipate for applications such as network interface cards (NICs), servers (note: servers, for instance, drive 40 percent of the power used in data centers), and fiber-optic transceivers, as well as the trade-off between switching speed and power efficiency. Power density hungry applications which can benefit from this invention in terms of reduced size and cost, and improved system efficiencies and others include HPC, data centers, AI, and 5G/6G covering switches, routers, servers, interface cards, optical transceivers, ASIC, processors, AI chips, FPGA, GPU, GaN high-electron-mobility transistor (HEMT), power semiconductors and high bandwidth data links such as peripheral component interconnect express (PCIe) and universial chiplet interconnect express (UCIe).

Consequently, there is a need of providing higher effective thermal conductivity composite semiconductor wafers of the largest size that the IC and IC assembly and test industries are capable of processing (for example, a diameter of 300 mm for Si based wafers, a diameter of 200 mm for SiC based wafers, or a diameter of 300 mm for GaN based wafers), which are formed by coating on the backsides of Si, SiC or GaN based wafers with high thermal dissipation layers (such as diamond, other high thermal conductivity materials or combinations thereof) for the fabrication of advanced ICs and advanced SiPs (covering interposers and advanced substrates) to enhance heat dissipation from chip hot spots and to obviate the drawbacks encountered by the prior art.

### SUMMARY

The present invention provides bi-wafers (with a diameter of 300 mm, 200 mm, 150 mm or others) which can be deployed using current IC foundry and wafer-level processes to create advanced ICs and advanced SiPs containing high thermal dissipation layers located in close proximity of chip hotspots to substantially reduce chip junction temperatures by as much as over 10° C., thereby enabling more IC functions to be integrated in the ICs and resulting in dramatic performance and reliability improvement. Using the bi-wafer approach, heat can now be dissipated both through the backside of the high-power logic dies and through the high thermal dissipation layers (such as diamond layers) in the bi-wafer enabled active ICs and interposers. This can dramatically enhance the dissipation of heat from the hot spots in high-power chips.

One object of the present disclosure is to provide a method to form a composite semiconductor wafer with a first dimension. The method comprises: preparing a plurality of composite blocks, wherein each composite block comprising a thermal dissipation layer and a semiconductor layer, the dimension of each composite block is smaller than the first dimension, and the thermal conductivity of the thermal dissipation layer is greater than that of the semiconductor layer; and merging the plurality of composite blocks to form the composite semiconductor wafer with the first dimension.

According to one aspect of the present disclosure, the process of preparing the plurality of composite blocks comprises: bonding a set of thermal dissipation layers on a semiconductor substrate; and dicing the semiconductor substrate with the set of thermal dissipation layers to form the plurality of composite blocks.

According to one aspect of the present disclosure, before the step of dicing, further comprising: depositing a filling material over the semiconductor substrate bonded with the set of thermal dissipation layers; and planarizing the filling material to reveal the set of thermal dissipation layers.

According to one aspect of the present disclosure, the thermal dissipation layer of each composite block is a diamond layer, the semiconductor layer of each composite block is a silicon layer, and the filling material is a silicon containing material such as silicon dioxide (SiO₂).

According to one aspect of the present disclosure, the process of bonding the set of thermal dissipation layers on the semiconductor substrate comprises: attaching the set of thermal dissipation layers to a temporary carrier; bonding the set of thermal dissipation layers on the temporary carrier to the semiconductor substrate, such that the set of thermal dissipation layers are bonded on the semiconductor substrate; and removing the temporary carrier.

According to one aspect of the present disclosure, each thermal dissipation layer is separate from one adjacent thermal dissipation layer at least by a dicing street distance after the set of thermal dissipation layers are attached to the temporary carrier.

According to one aspect of the present disclosure, the process of merging comprises: attaching the plurality of composite blocks to a temporary substrate; depositing a molding material over the plurality of composite blocks and the temporary substrate; planarizing the molding material to reveal the plurality of composite blocks; and removing the temporary substrate to form the composite semiconductor wafer with the first dimension.

According to one aspect of the present disclosure, the first dimension is approximate to 300 mm.

According to one aspect of the present disclosure, the process of preparing the plurality of composite blocks comprises: preparing a semiconductor substrate with a thermal dissipation film thereon; and dicing the semiconductor substrate with the thermal dissipation film to form the plurality of composite blocks.

According to one aspect of the present disclosure, the process of preparing the semiconductor substrate with the thermal dissipation film thereon comprises: preparing the semiconductor substrate; forming the thermal dissipation film over the semiconductor substrate; and depositing a sacrificial layer over the thermal dissipation film and planarizing the sacrificial layer to form the semiconductor substrate with the thermal dissipation film.

According to one aspect of the present disclosure, the thermal dissipation film is a diamond film and the sacrificial layer is a silicon containing material such as SiO₂.

According to one aspect of the present disclosure, the process of preparing the semiconductor substrate with the thermal dissipation film thereon comprises: attaching the semiconductor substrate to a temporary carrier; depositing the thermal dissipation film over the semiconductor substrate; depositing a sacrificial layer over the thermal dissipation film and planarizing the sacrificial layer; and removing the temporary carrier to form the semiconductor substrate with the thermal dissipation film.

According to one aspect of the present disclosure, the process of preparing the plurality of composite blocks comprises: depositing a thermal dissipation film over a set of semiconductor chips to form a semiconductor substrate with the thermal dissipation film; and dicing the semiconductor substrate with the thermal dissipation film to form the plurality of composite blocks.

According to one aspect of the present disclosure, the process of depositing the thermal dissipation film over the set of semiconductor chips comprises: preparing the set of semiconductor chips; forming the thermal dissipation film over the set of semiconductor chips; and depositing a sacrificial layer over the thermal dissipation film and planarizing the sacrificial layer to form the semiconductor substrate with the thermal dissipation film.

According to one aspect of the present disclosure, the thermal dissipation film is a diamond film and the sacrificial layer is a silicon containing material such as SiO₂.

According to one aspect of the present disclosure, the step of depositing the thermal dissipation film over the set of semiconductor chips comprises: attaching the set of semiconductor chips to a temporary carrier; forming the thermal dissipation film over the set of semiconductor chips; depositing a sacrificial layer over the thermal dissipation film and planarizing the sacrificial layer; and removing the temporary carrier to form the semiconductor substrate with the thermal dissipation film.

Another object of the present disclosure is to provide a method to form a composite semiconductor wafer with a first dimension, comprising: attaching a set of thermal dissipation layers to a temporary carrier; bonding the set of thermal dissipation layers on the temporary carrier to a semiconductor substrate with the first dimension, such that the set of thermal dissipation layers are bonded to the semiconductor substrate; and removing the temporary carrier to form the composite semiconductor wafer with the first dimension.

According to one aspect of the present disclosure, the process to form a composite semiconductor wafer with the first dimension further comprises: depositing a filling material over the semiconductor substrate bonded with the set of thermal dissipation layers; and planarizing the filing material to reveal the set of thermal dissipation layers.

According to one aspect of the present disclosure, the semiconductor substrate is a Si substrate, the filling material is a Si based material such as SiO₂, and the thermal dissipation layer is made of diamond.

According to one aspect of the present disclosure, each thermal dissipation layer is separate from one adjacent thermal dissipation layer at least by a dicing street distance after the set of thermal dissipation layers are attached to the temporary carrier.

Another object of the present disclosure is to provide a semiconductor structure which comprises a substrate and a composite semiconductor chip bonded to the substrate; wherein the composite semiconductor chip is derived from the composite semiconductor wafer according to the present invention, and includes a thermal dissipation side and a semiconductor side.

According to one aspect of the present disclosure, the semiconductor structure further comprises another semiconductor chip bonded to the semiconductor side of the composite semiconductor chip.

According to one aspect of the present disclosure, the semiconductor structure further comprises another composite semiconductor chip bonded to the composite semiconductor chip.

One object of the present disclosure is to provide a heterogeneous semiconductor structure: the heterogeneous semiconductor structure comprises a substrate and a composite semiconductor chip over the substrate; wherein the composite semiconductor chip includes a thermal dissipation layer and a semiconductor layer and the thermal dissipation layer directly contacts the semiconductor layer without any adhesive material between the thermal dissipation layer and the semiconductor layer.

According to one aspect of the present disclosure, the heterogeneous semiconductor structure further comprises another semiconductor chip electrically connected to the composite semiconductor chip, wherein the semiconductor layer of the composite semiconductor chip includes a first plurality of active circuits and the another semiconductor chip includes a second plurality of active circuits. The active circuits could include transistors.

According to one aspect of the present disclosure, the heterogeneous semiconductor structure further comprises another composite semiconductor chip electrically connected to the composite semiconductor chip, wherein the another composite semiconductor chip comprises another thermal dissipation layer and another semiconductor layer bonded to the another thermal dissipation layer.

One object of the present disclosure is to provide a heterogeneous semiconductor structure, the heterogeneous semiconductor structure comprises a substrate and a composite semiconductor chip over the substrate; wherein the composite semiconductor chip includes a thermal dissipation layer, a semiconductor layer, and a molding compound covering sidewalls of the thermal dissipation layer and the semiconductor layer.

According to one aspect of the present disclosure, the heterogeneous semiconductor structure further comprises another semiconductor chip electrically connected to the composite semiconductor chip, wherein the composite semiconductor chip includes a first plurality of through vias and the another semiconductor chip includes a plurality of active circuits.

According to one aspect of the present disclosure, the heterogeneous semiconductor structure further comprises another composite semiconductor chip electrically connected to the composite semiconductor chip, wherein the composite semiconductor chip includes a first plurality of through vias, another composite semiconductor chip includes another thermal dissipation layer and another semiconductor layer, and another thermal dissipation layer directly contacts another semiconductor layer without any adhesive material between the another thermal dissipation layer and the another semiconductor layer. (PS: “the another” is necessary due to claim grammar.)

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1 is a cross-sectional view illustrating a plurality of diamond plates bonded to a temporary carrier to reconstitute a twelve-inch (300 mm) wafer.

FIG. 2 describes the manufacture method for the composite semiconductor wafer according to one embodiment of the present invention via low-temperature bonding.

FIG. 3A describes the manufacture method to form the composite blocks according to one embodiment of the present invention.

FIG. 3B describes the manufacture method to form the composite blocks according to another embodiment of the present invention.

FIG. 4A describes the manufacture method to form the composite blocks according to other embodiment of the present invention.

FIG. 4B describes the manufacture method to form the composite blocks according to another embodiment of the present invention.

FIG. 5 describes the manufacture method to form the composite semiconductor wafer by merging the composite blocks according to one embodiment of the present invention.

FIG. 6A and FIG. 6B illustrate exemplary advanced SiP packages with the composite block based on which the ICs are formed according to one example of the present invention.

FIG. 7 is a complex SiP package based on the ICs derived from the composite block with the diamond layer and the semiconductor layer according to one example of the present invention.

FIG. 8 is a diagram of the conventional 2.5D IC package with high bandwidth memory (HBM) DRAM dies positioned on a base die, and logic ICs.

### DETAILED DESCRIPTION

It is to be noted that the following descriptions of preferred embodiments of this disclosure are presented herein for the purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regarded in an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

Diamond has the highest thermal conductivity of any known material at temperatures above ˜100° K, which is >5× that of copper. Diamond also comes with high electrical resistivity (diamond can insulate high voltages across much thinner layers of material) and high electrical breakdown field. Diamond has a very low coefficient of thermal expansion. Diamond's electronic band gap is bigger than silicon, and the two mainstream wide-band-gap materials, SiC and GaN for power electronics. Wider band gaps means less of the material is needed to transmit electricity and electronic signals at higher voltages and frequencies. Diamond possesses a unique combination of extreme properties:

| Diamond | Copper, Silicon, SiC or GaN |
|---|---|
| Thermal conductivity (W/cm. | vs. ~4 for copper, 1.5 for silicon, ~3 |
| ° K): ~24 | for GaN and 5 for SiC-4H |
| Breakdown field (MV/cm): 20 | vs. 0.3 for silicon, 5 for GaN and 3 |
| | for SiC-4H; |
| Electron mobility (cm²/Vs): | vs. 1,450 for silicon, 440 for GaN and |
| 4,500 | 900 for SiC-4H |
| Hole mobility (cm²/Vs): 3,800 | vs. 480 for silicon, 200 for GaN and |
| | 120 for SiC-4H |
| Band gap (eV): 5.5 | vs. 3.44 for GaN and 3.2 for SiC-4H |

Significant progress has been made in the recent past in growing larger, high-quality diamond wafers/plates. High-quality, electronic grade diamond films (created typically by microwave enhanced chemical vapor deposition, MPCVD) presents an excellent opportunity for heat dissipation, and could be implemented to create a new breed of advanced ICs and advanced SiPs for the aforementioned high power and 5G/6G applications, taking advantage of diamond's “extreme” properties, notably, extreme thermal conductivity (˜24 W/cm. ° K) which is >5× that of copper, extremely high breakdown field (˜20 MV/cm), and extremely low thermal expansion coefficient (˜1 ppm/° C. at room temperature).

For silicon-diamond bi-wafers to be practical for HPC and other high-power applications, they have to be in 300 mm diameter, the largest wafer size in mainstream IC fabrication and wafer-level processes today, for productivity and cost reasons. By the same token, 200 mm SiC-diamond substrate is required for SiC applications (note: SiC is available commercially now in 200 mm-diameter wafers). Diamond today can only be grown commercially to a size/diameter of ˜140 mm in terms of polycrystalline diamond (PCD), and is available in the form of 50 mm×50 mm high-quality single-crystal diamond (SCD) plates up to 0.5 mm thick. These sizes are still much smaller than 300 mm, which is required by 300 mm silicon-diamond bi-wafers, and smaller than 200 mm, required by SiC-diamond bi-wafer. It took silicon wafer about 35 years to scale from 50 mm-diameter wafer (around the year 1965) to 300 mm-diameter wafer (around 2000), and about 20 years from 125 mm or 150 mm to 300 mm.

The following embodiments pertain to the manufacture of 300 mm (or 200 mm) bi-wafers with a target semiconductor (such as Si, SiC or GaN) and a high thermal conductivity layer (such as diamond) thereon, and the thermal conductivity of such high thermal conductivity layer is higher than that of the target semiconductor. For example, this invention discloses processes and structures to create silicon-diamond bi-wafers of 300 mm in diameter starting from a diamond substrate which is smaller than 300 mm in diameter for use in creating silicon-diamond bi-wafer enabled advanced ICs and advanced SiPs with examples to be shown below for demonstration purposes.

### Embodiment 1

According to one embodiment of the present disclosure, a full-sized of bi-wafer is formed by direct bonding of diamond to a full-sized silicon wafer (with a diameter of 300 mm or 200 mm) at room-temperature (or low-temperature), the process includes steps as follows:
Step S21: preparing a plurality of diamond plates;
Step S22: bonding the plurality of diamond plates to a temporary carrier;
Step S23: bonding the temporary carrier with the plurality of diamond plates to a full-sized semiconductor wafer;
Step S24: removing the temporary carrier from the plurality of diamond plates and the full-sized semiconductor wafer;
Step S25: depositing a covering layer on the full-sized semiconductor wafer with the plurality of diamond plates to form the full-sized bi-wafer.

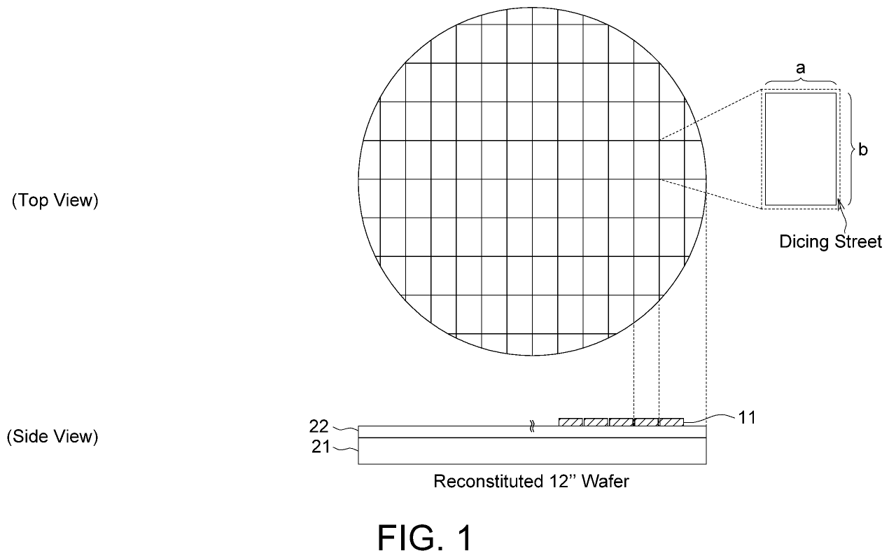

Referring to Step S21: a plurality of diamond plates 11 (FIG. 1) are prepared, especially, the size of each diamond plate will be dependent on the foundry's technology node. For example, when the full-sized semiconductor wafer has a diameter of 300 mm and the technology node is 3˜10 nm, the maximum size of each diamond plate can be 26 mm by 33 mm due to the extreme ultraviolet (EUV) lithography steppers have a maximum field size of 26 mm by 33 mm. It is possible that the size of each diamond plate could be smaller than the maximum field size of the lithography steppers.

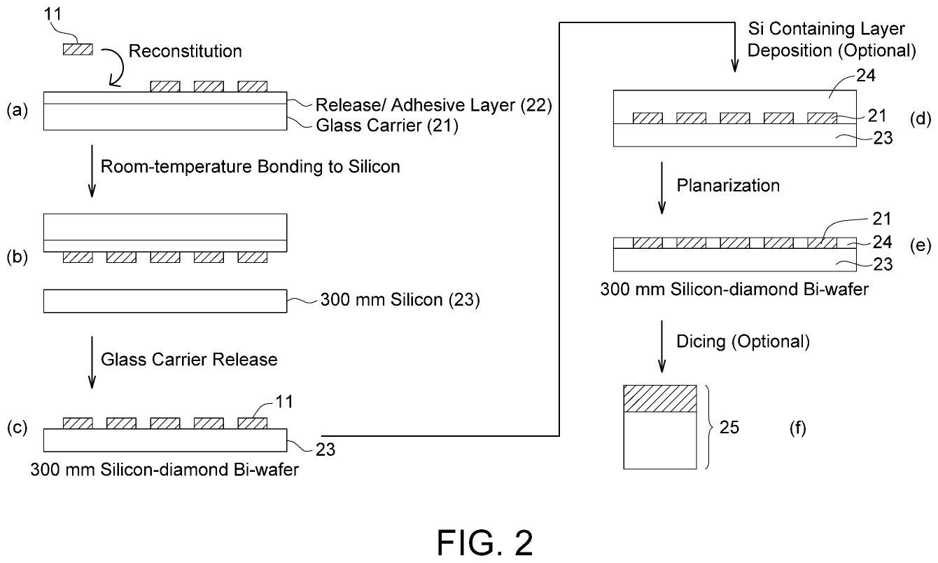

Referring to Step S22: bonding the plurality of diamond plates 11 to a temporary carrier. As shown in FIG. 2(a), the plurality of diamond plates will be bonded to a temporary carrier (such as a glass carrier 21) through a release/adhesive layer 22. Further referring to FIG. 1, the size of each diamond plate is a times b, and there is a gap (dicing street) between every two adjacent diamond plates. That is, using diamond plates 11 of, preferably, a and b in length and width, respectively, i.e., the final die or interposer sizes, to reconstitute a 300 mm wafer as shown in FIG. 1. These diamond plates 11 of desired sizes can be obtained by laser dicing of the larger diamond plates (say, ˜140 mm in diameter, the largest size based on CVD PCD). The diamond plates 11 are attached to the 300 mm glass carrier 21 with a release/adhesive layer 22. The release/adhesive layer 22 can be the polymer layers used in mainstream fan-out processes. It can also be a combination of Au (gold) on the glass carrier and Au on the backside of diamond. Au here can also be replaced by Cu (copper) or a solder on both surfaces. Compression or reflow bonding can be used to achieve the bonding of diamond plates 11 to the glass carrier 21 when a metal such as Au, Cu or a solder is used. Prior to gold or copper deposition and as needed, thin metallization based on titanium (Ti), tungsten (W) or chromium (Cr) which makes a chemical bond with diamond can also be deposited, followed by deposition of typically palladium (Pd) or platinum (Pt) as a diffusion barrier and finally copper or gold can be deposited to prepare the diamond for soldering, eutectic bonding, or wire bonding. Annealing is optional and can be done on an as-needed basis. A typical Ti/Pt/Au metallization is 1,000 Å/1,000 Å/10,000 Å thick on diamond. This can also be applied to the glass carrier 21 as needed.

Referring to Step S23: bonding the temporary carrier with the plurality of diamond plates to a semiconductor wafer. As shown in FIG. 2(b), the glass carrier 21 with the diamond plates 11 is bonded to the silicon wafer 23 of 300 mm in diameter which is a popular and commercially available size for current foundry and wafer-level processes. In this step, low-temperature (e.g., room-temperature) direct bonding can be used. Low-temperature direct bonding involves use of ions or neutral atoms in vacuum to physically remove the oxide films on the surfaces of the substrates to be bonded, thereby forming dangling bonds on the surfaces which subsequently enable the direct bonding. Thus, it is not necessary to use the adhesive material during the low-temperature direct bonding.

To achieve high low-temperature direct bonding yield between diamond and silicon: (1) the front side (the side to be bonded to silicon) surface of the diamond plates 11 can be pre-deposited as needed with a thin silicon or silicon oxide layer as an activation layer followed as needed by CMP (to control its RMS that is root mean square average surface roughness) to nm scale; (2) bonding surfaces are cleaned by fast atom beam (“FAB”) gun (using argon, Ar, neutral atom beam) or ion gun (using Ar ion) to remove the oxide film, for instance, on the wafer surface in vacuum and to create dangling bonds at the surfaces. FAB works well for Si/Si, Si/SiO₂, metals, compound semiconductors and single crystal oxides while ion gun is known to work for SiO₂/SiO₂, Glass, silicon nitride (Si₃N₄)/Si₃N₄, Si/Si, Si/SiO₂ metals, compound semiconductor, and single crystal oxide; (3) a vacuum of 10⁻⁶ Pa (pascal) is required during bonding to prevent re-adsorption to activated bonding surfaces above; and (4) surface roughness of ˜1 nm Ra (arithmetic mean surface roughness) is preferred for both diamond and silicon. This level of Ra is achievable by CMP for silicon, and by sacrificial SiO₂ layer deposition, SiO₂ planarization by CMP and dry reactive ion etching (DRIE) for diamond.

Referring to Step S24: removing the temporary carrier from the plurality of diamond plates and the full-sized semiconductor wafer. As shown in FIG. 2(c), the glass carrier 21 is then removed from the silicon wafer 23 with the diamond plates 11: (1) Using a laser and a debonder which are typically used in mainstream fan-out processes when a polymeric release/adhesion layer is used; or (2) if a metal is used, wet etching to remove Au or Cu (or solder) from the glass carrier 21. Mixtures of nitric acid and hydrochloric acid (in a mixing ration of 1:3; also called aqua regia) are able to etch gold at room temperature. Copper is etched by nitric acid as well as saturated 30% FeCl₃ solution. Mixtures of NH₄OH and H₂O₂ etch copper as well.

Step S25: depositing a covering layer on the full-sized semiconductor wafer. As shown in FIG. 2(d), a silicon containing layer 24 could be deposited when needed on the silicon wafer 23 with the diamond plates 11 to fill the gaps between the diamond plates 11. That is, one can optionally deposit SiO₂ (or other high-temperature materials) on 300 mm wafers, followed by planarization (FIG. 2(e)) involving standard silicon processing tools for backgrinding, polishing and/or CMP. These extra steps are aimed to fill the spaces between the diamond plates 11. Thus, a full-sized of 300 mm-diameter bi-wafer is achieved and ready for IC foundry and wafer-level processes to produce advanced ICs and advanced SiPs.

In the event the semiconductor substrate 23 has already been processed by semiconductor foundry and includes semiconductor circuits therein, then after dicing, the composite block 25 with semiconductor circuits in the semiconductor layer could be subjected to follow-on IC packaging, i.e., IC assembly and test processes. Otherwise, the full-sized composite semiconductor wafer (such as 300 mm silicon-diamond bi-wafer) in FIG. 2 could be processed in semiconductor foundry for producing semiconductor circuits and both semiconductor and wafer-level foundries for interposers therein and then optionally diced into composite blocks 25 for subsequent IC packaging purposes.

The diameter of the composite semiconductor wafer could be 300 mm, 200 mm, or 150 mm, depending on the technology node adopted by the semiconductor foundry for producing semiconductor circuits therein. The aforesaid manufacturing processes could be applied to other bi-wafers, such GaN-diamond bi-wafers of 300 mm in diameter or SiC-diamond bi-wafers of 200 mm in diameter. Moreover, diamond could be replaced by other types of high thermal conductivity materials or combinations thereof.

In another embodiment, the diamond plates 11 could be placed on a semiconductor substrate, as shown or an active IC wafer in the above, and then diced into the composite blocks 25, wherein each composite block 25 comprises a thermal dissipation layer (a thermal conductivity layer such as diamond) and a semiconductor layer, as shown in FIG. 2(f), for subsequent IC packaging purposes. It is mentioned that, due to the aforesaid low-temperature direct bonding, the composite blocks 25 does not have adhesive material between the thermal dissipation layer and the semiconductor layer in one embodiment.

### Embodiment 2

According to another embodiment of the present disclosure, the method for forming a full-sized bi-wafer includes steps as follows:
Step S31: depositing a thermal dissipation (or high thermal conductivity) layer such as diamond on a semiconductor substrate of a first diameter;
Step S32: dicing the semiconductor substrate of the first diameter that is deposited with the thermal dissipation layer into a plurality of composite blocks; and
Step S33: merging the plurality of composite blocks to form the full-sized bi-wafer (or the composite semiconductor wafer with a first diameter).

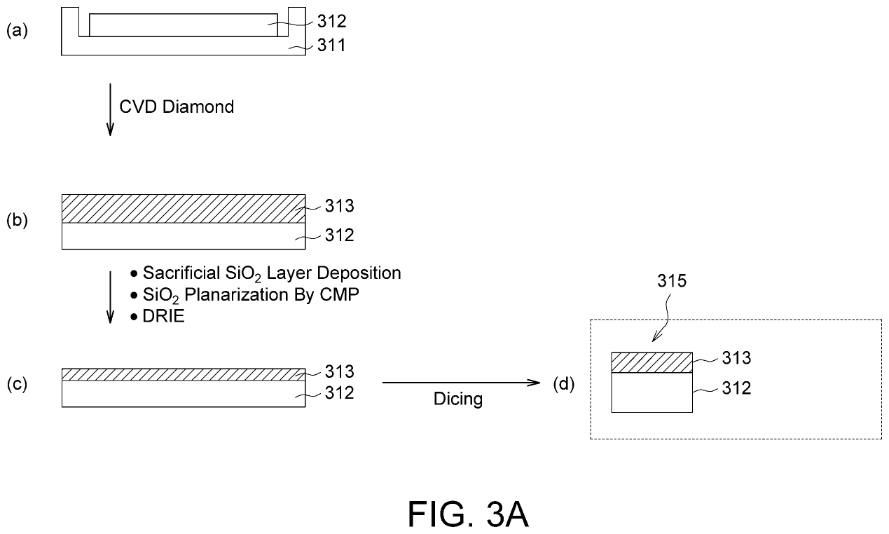

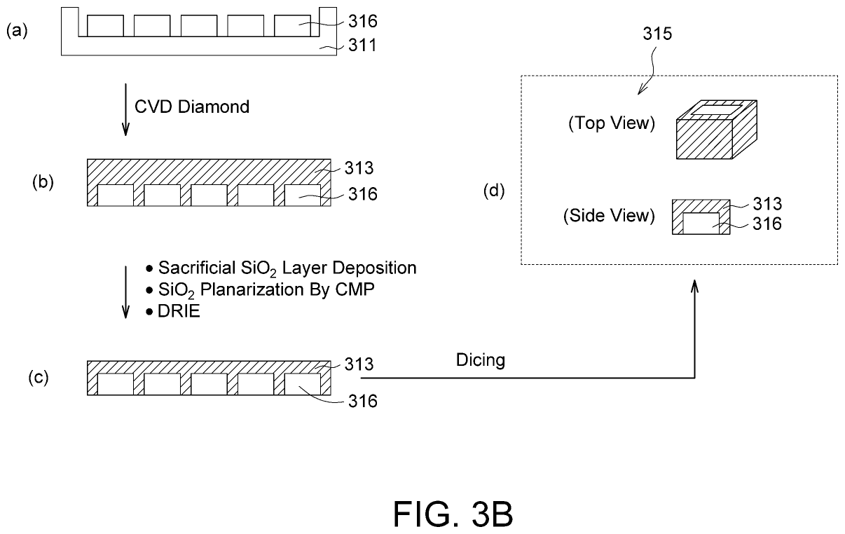

Referring to Step S31: depositing a thermal dissipation layer on a predetermined diameter semiconductor substrate. As show in FIG. 3A(a)˜FIG. 3A(c), a predetermined diameter semiconductor substrate (such as Si, SiC, or

GaN) is positioned into a holder (FIG. 3A(a)), and then the thermal dissipation layer (such as diamond) is deposited on the surface of the predetermined diameter semiconductor substrate. For example, a silicon substrate 312 (e.g., of a predetermined diameter of 150 mm) can be cored (with appropriate wafer edge beveling) to a size/diameter of ˜140 mm (that is the maximum size of PCD today) and background to a desired thickness as needed. It can be placed on top of the substrate holder 311 inside the microwave plasma CVD chamber. After silicon substrate placement, MPCVD deposition of the diamond layer 313 (FIG. 3A(b)) then commences, followed by a sequence of intermediate or sacrificial SiO₂ layer deposition (not shown), SiO₂ planarization by CMP and deep reactive ion etching (DRIE) using, for instance, a gas mixture of SF₆ and O₂ (FIG. 3A(c)).

The MPCVD diamond 313 is capable of producing commercially ultrapure electronic grade CVD diamond at high growth rates over large areas with nitrogen concentration <5 ppb. CVD diamond can be synthesized from a mixture of H₂/CH₄/N₂ gas mixture. The MPCVD diamond deposition is sensitive to many process parameters such as gas pressure in the reactor, methane concentration, substrate/carrier temperature, absorbed microwave power density, nitrogen contamination and substrate/carrier holder geometry. Growth rates of up to 165 μm/hour at 300 torrs has been achieved at a high power density with N₂ addition in gas. The smoothing process involving DRIE here is capable of achieving a root mean square average surface roughness (RMS) on the order of nm for PCD based on 50 mm wafers. For SCD, however, a RMS of <1 nm can be achieved. Prior to CVD deposition of diamond, it is advantageous to subject silicon surfaces to surface treatment similar to that used for room-temperature direct bonding for better diamond quality control. The choice of substrate (e.g., Si) to grow diamond is crucial as it can affect the crystalline quality of diamond films. The criteria for substrate selection are many, and they include crystal structure, lattice constant, thermal expansion coefficient, substrate stability under CVD, and surface reactivity which is critical for diamond nucleation. The film's quality is intimately linked to the disorientation of the nuclei. The formation of a continuous diamond film on Si during CVD deposition requires a sufficiently high density of nuclei on the surface. To further enhance the quality of CVD diamond films, one can consider use of iridium which is known to be behave order of magnitude better than other non-diamond materials including Si, SiC, TiC, cobalt (Co) , Pt, Ni, rhenium (Re), and aluminium oxide (Al₂O₃) when it comes to the quality of CVD diamond films. To limit the cost of the substrates, to reduce thermal stresses and to migrate towards larger substrates, one can use multilayered substrates containing iridium on metal oxide layers on silicon substrates which is the focus here, and this also applies to oxide substrates such as magnesium oxide (MgO), and sapphire.

Referring to Step S32: dicing the first diameter semiconductor substrate deposited with the thermal dissipation layer. As shown in FIG. 3A(c) and FIG. 3A(d), the semiconductor substrate 312 deposited with the diamond layer 313 finished in Step S31 is diced into a plurality of composite blocks 315, each composite block includes a semiconductor layer (such as Si) and a thermal dissipation layer (such as diamond). Lasers such as a Q-switched Nd:YAG laser can be used for sawing/dicing diamond at its fundamental wavelength of 1064 nm wavelength or a multiple of that, whereas silicon dicing can be done using conventional mainstream methods. Bread slicing using lasers can be performed to remove diamond structures from carriers.

In Step S31, alternatively, a plurality of second diameter semiconductor substrate 316 (FIG. 3B(a)), instead of the bigger first diameter semiconductor substrate, are placed on top of the substrate holder 311 inside the MPCVD chamber (FIG. 3B(a)). Then, as shown in FIG. 3B(b) and FIG. 3B(c), MPCVD deposition of the diamond layer 313 (FIG. 3B(b)) then commences, followed by a sequence of intermediate or sacrificial SiO₂ layer deposition (not shown), SiO₂ planarization by CMP and DRIE using, for instance, a gas mixture of SF₆ and O₂ (FIG. 3B(c)). As can be seen in (FIG. 3B(d)), after dicing, the individual silicon-diamond composite block 315 here is encased by diamond on all five sides.

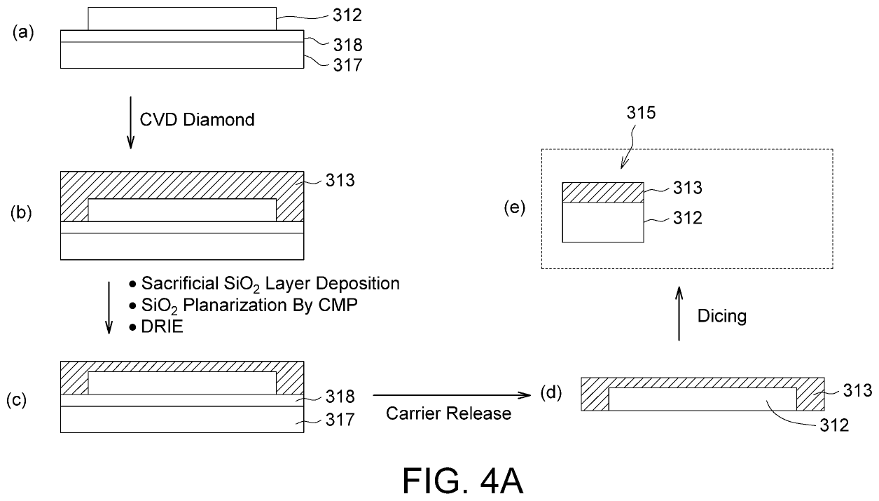

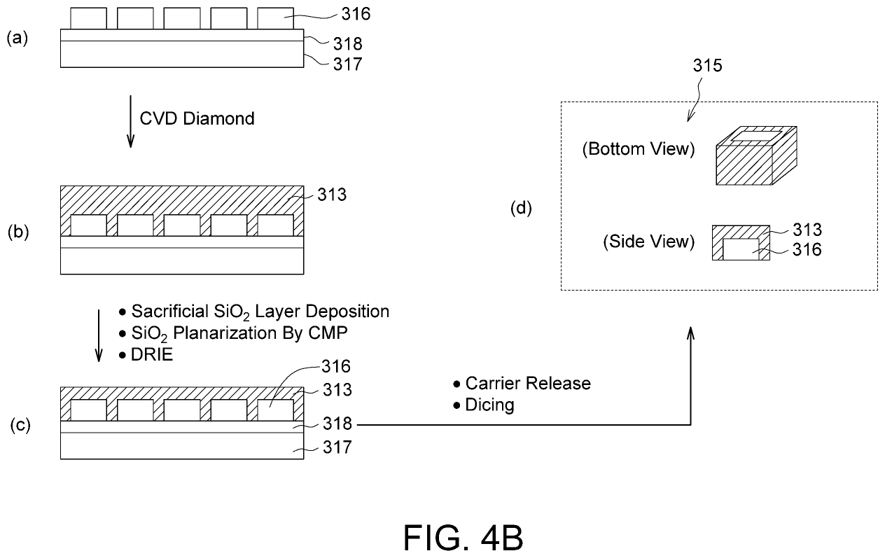

In Step S31, alternatively, as shown in FIG. 4A(a)- FIG. 4A(d), the first diameter semiconductor substrate 312 could be first attached to a temporary carrier 317 through an adhesive layer 318 (FIG. 4A(a)), then MPCVD deposition of the diamond layer 313 (FIG. 4A(b)) commences, followed by a sequence of intermediate or sacrificial SiO₂ layer deposition (not shown), SiO₂ planarization by CMP and DRIE using, for instance, a gas mixture of SF₆ and O₂ (FIG. 4A(c)). Thereafter, the temporary carrier 317 is removed or released by lasers and wet etching and cleaning (FIG. 4A(d)). That is, the first diameter semiconductor substrate 312 can also be bonded as needed through a release/adhesive layer 318 to a carrier which is again ˜140 mm in size. When the release/adhesive layer 318 and the carrier are used, they should be able to withstand the high temperatures (typically, 750° C. to 1000° C.) incurred during subsequent CVD diamond deposition.

The carrier can be a CVD diamond seed material including SCD, or HPHT (high pressure, high temperature) diamond, silicon or other non-diamond-containing substrates, for example, iridium (with a melting point of 2410° C.). When diamond is used as the carrier, the carrier can be pre-treated using techniques such as H₂/O₂ plasma etching, reactive ion etching- inductively coupled plasma etching, and/or CMP to rid of surface defects and prevent induction of defects during CVD diamond deposition such as threading, and dislocations. Also, {100}-oriented diamond is preferred as the {100} crystal orientation yields the lowest density of structural defects. In addition to {100} orientation, {111} and {113} orientations can also produce reasonably good quality films. Depending on diamond deposition temperatures, metal release/adhesive candidates here to bond silicon to carrier can be Au (melting point 1064° C.) or Cu (melting point 1084.62° C.) as in the case of room-temperature direct bonding or they can include higher-melting refractory metals or their alloys that can be bonded to copper on one side. Vacuum brazing involving active brazes can also be used to braze diamond parts to other materials (such as steel tool shanks and inserts in vacuum or in an inert atmosphere). They may also work here.

In Step S31, alternatively, as shown in FIG. 4B(a)˜FIG. 4B(d), a plurality of second diameter semiconductor substrates 316, instead of the bigger first diameter semiconductor substrate 312, are attached to the temporary carrier 317 through an adhesive layer 318 (FIG. 4B(a)), then MPCVD deposition of the diamond layer 313 (FIG. 4B(b)) commences, followed by a sequence of intermediate or sacrificial SiO₂ layer deposition (not shown), SiO₂ planarization by CMP and DRIE using, for instance, a gas mixture of SF₆ and O₂ (FIG. 4B(c)). Thereafter, the temporary carrier 317 is removed or released by laser, wet etching and cleaning as needed. Following dicing one can begin by bonding the singulated silicon substrates 316 (pre-diced to achieve approximately the final length and width of the interposer or die) to the carrier 317, followed by CVD diamond, sacrificial SiO₂ layer deposition and planarization, DRIE, carrier release and dicing to form the silicon-diamond structure which is coated with diamond on five sides. This type CVD diamond growth resembles “mosaic growth,” a newly developed technique used to extend SCD size. Mosaic SCD wafers as large as 40 mm×60 mm can be produced on arrays of 10 mm×10 mm “clone” substrates placed at the CVD holder. By growing a thick CVD layer, mosaic growth enlarges the initial area of the substrate/carrier (say 10 mm×10 mm) as growth also occurs laterally from the substrates/carriers. As can be seen in

(FIG. 4B(d)), after dicing, the individual silicon-diamond composite block 315 here is encased by diamond on all five sides.

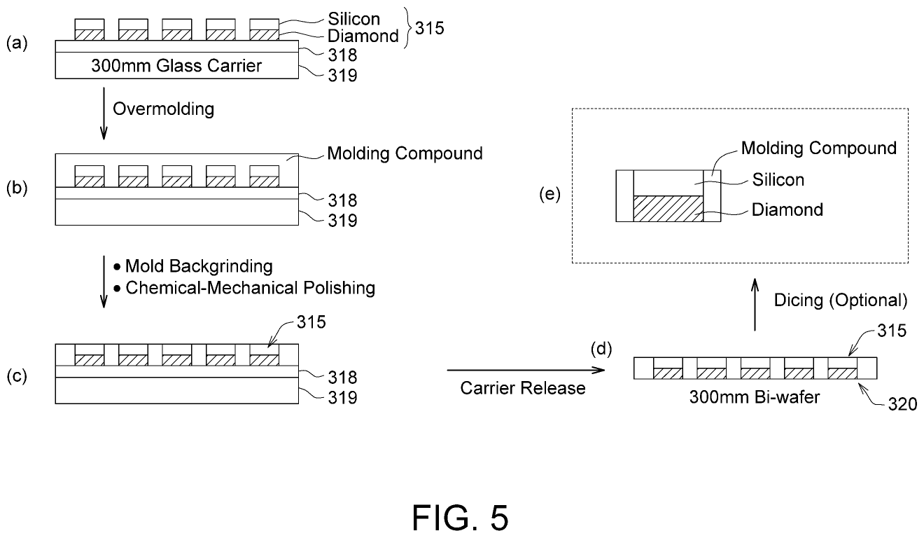

Step S33: merging the plurality of composite blocks to form the full-sized bi-wafer (or the composite semiconductor wafer with the first diameter). After the formation of the individual silicon-diamond composite blocks 315, one can then proceed to bond the composite blocks 315 onto a 300 mm glass carrier 319 with a polymeric release/adhesive layer 318 (FIG. 5(a)) as in the case of mainstream fan-out processing to reconstitute the 300 mm wafer with the composite blocks 315 shown in FIG. 3A˜FIG.4B. Having completed the 300 mm wafer reconstitution, one can then proceed to follow part of the fan-out processing from over-molding to mold back-grinding, CMP as needed, and carrier release to form the 300 mm silicon-diamond bi-wafer 320 as shown in FIG. 5(b)˜FIG. 5(d). The 300 mm silicon-diamond bi-wafer 320 can be used to form the interposes used in advanced IC packages.

In the reconstitution step, the accuracy can be enhanced by wafer notch, wafer flat and alignment marks to an accuracy of around ±1 μm, which is still far smaller than the width of the dicing street shown in FIG.1. During reconstitution, the composite blocks 315 should be placed as closed as possible to minimize waste of silicon real estate while still allowing high-yielding silicon diamond processing and subsequent dicing.

The combined thickness of the 300 mm silicon-diamond bi-wafer 320 can be adjusted according to cost performance, cycle time, reliability as well as time-to-market requirements. This applies to both bi-wafer enabled ICs and SiPs. Diamond costs higher than silicon and therefore diamond thickness should be thin and adjusted to be small enough for cost yet large enough to achieve enhanced thermal management. On the other hand, silicon can be background to the desired thickness such that the bi-wafers formed can have the final desired thickness. It is also worth noting in passing that the 300 mm bi-wafers created by the approaches shown in FIGS. 2, 3A, 3B, 4A, 4B and 5 can be used to generate a new breed of advanced ICs and advanced SiPs.

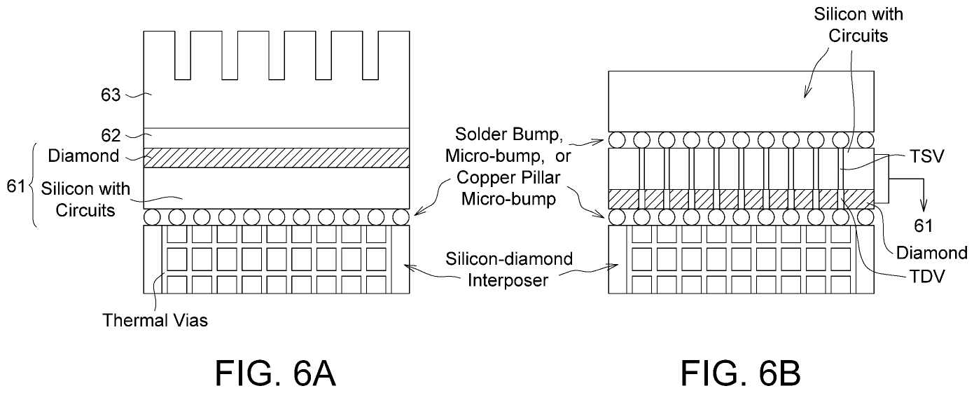

As shown in FIG. 6A, the full-sized composite semiconductor wafer (such as the 300 mm silicon-diamond bi-wafer) can be used to create high-performance processor IC 61 cooled by diamond on the backside of the processor IC 61 as well as by the conventional heat spreader 62 and heat sink 63 with thermal interface materials (e.g., thermal paste and graphene containing materials) between diamond and heat spreader 62, and between heat spreader 62 and heat sink 63. The processor IC 61 could be derived from the full-sized silicon-diamond bi-wafer (FIG. 2) with the diamond layer and the semiconductor layer described in the above. The hot spots in the processor IC 61 in FIG. 6A can be cooled by diamond located in close proximity on the chip's backside.

It is also possible to use the diamond layer and the semiconductor layer in the fabrication of high-end DRAM to form known-good-die DRAM with or without the solder bumps so long as burn-in and sufficient test coverage can be performed prior to shipment. The 300 mm bi-wafer can also be deployed to build the processor IC 61 which can be assembled with a DRAM IC on top in a 3D or SiP package in support of in-memory computing as shown in FIG. 6B, where the processor IC 61 contains both through silicon vias (TSVs) in silicon layer which are created by the mainstream 2.5D TSV processes, and through diamond vias (TDVs) in diamond layer which are new to the industry.

The main difference between the creation of TSVs in 2.5D mainstream production today, and the creation of TDVs lies in the hole or via opening process. The TSV vias are created by DRIE of silicon using fluorinated gases such as CF₄, SF₆ or xenon difluoride (i.e., the Bosch etch process) as the etch gas, while the TDVs rely on DRIE utilizing oxygen as the etch gas (and other heavier gases such as CF₄) and a mask such as aluminum/silicon dioxide, aluminum/silicon/aluminum, or stainless steel, to create the high-aspect ratio through diamond vias (e.g., thousands of them of 20 μm in diameter at an aspect ratio of 5) at high etch rates. Other mask choices that can be considered include aluminum, titanium, gold, chromium, silicon dioxide, aluminum oxide, photoresist and/or spin-on-glass. The etch mask material needs to be etched slower than diamond in DRIE with high selectivity. Ultra-short-pulse (e.g., femtosecond-pulsed) laser micromachining can also be used depending on the mask and DRIE conditions for improved etch performance. A combination of DRIE and epitaxial deposition can create ultra-high-aspect-ratio (up to 500) trenches in silicon. It may also be fashioned after to create ultra-high-aspect-ratio TDVs.

Both structures shown in FIGS. 6A and 6B can be supported by laminate substrates or silicon-diamond bi-wafer enabled interposers with through vias. The bottom diamond layer of the processor IC 61 could also be positioned on the side facing the interposer which also includes a diamond layer and a semiconductor layer (“silicon-diamond interposer”).

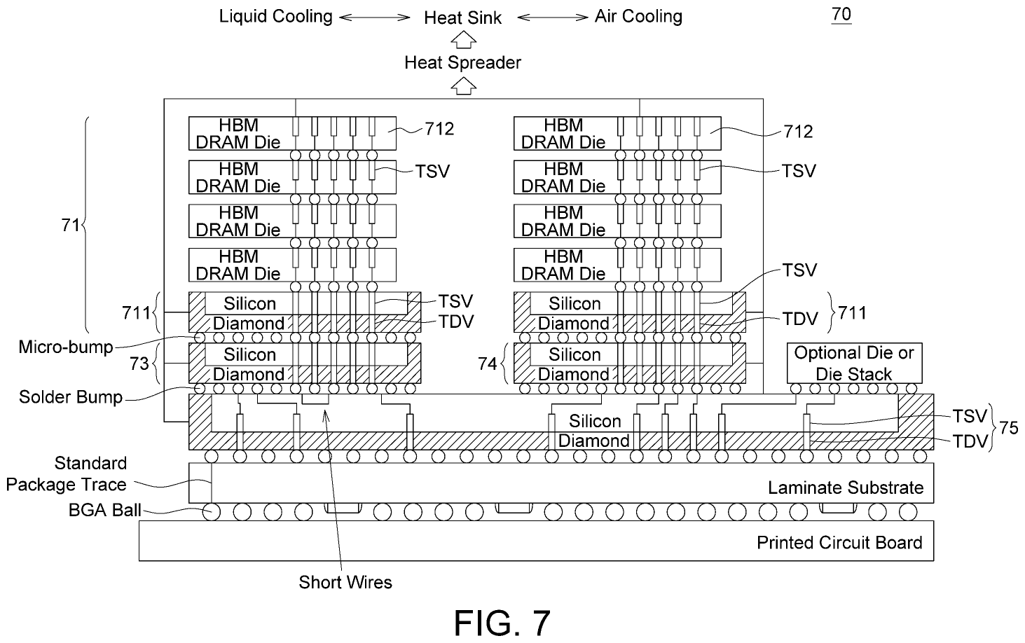

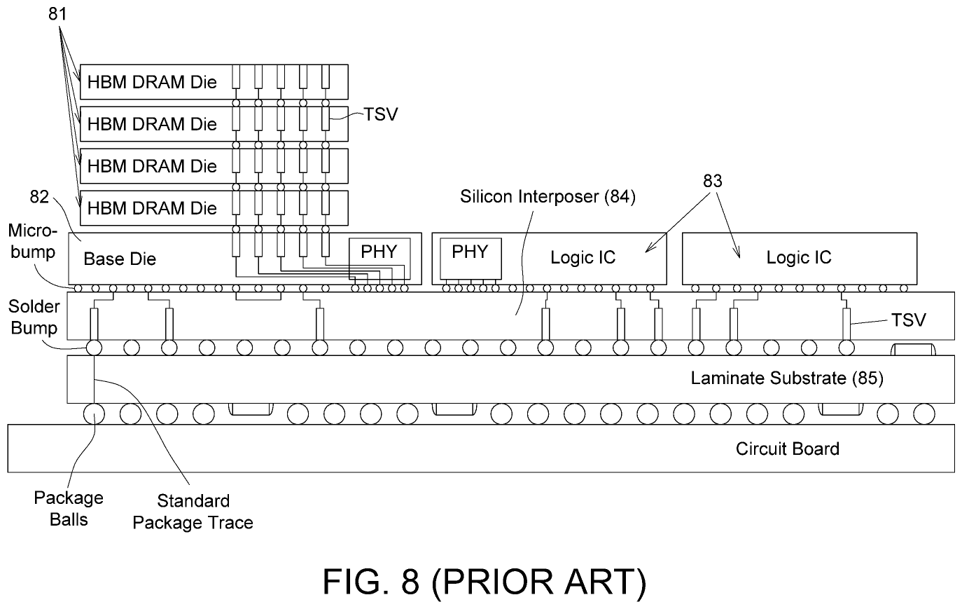

More complex SiP packages based on the processor IC 61 can also be formed as shown in FIG. 7. FIG. 7 shows a 2.5D and 3D IC package 70 wherein 300 mm silicon-diamond bi-wafer (FIG. 2) are used to fabricate the control die 711 (and possibly also the high-bandwidth DRAM 712 (HBM) in the HBM stack 71), the GPU 73 and the CPU 74 under their respective HBMs 71, and on top of the interposer 75. In the conventional 2.5D IC (FIG. 8), heat dissipation is carried out through the backside of the flip chip bonded high-power compute and/or processor dies using heat spreader, thermal interface material and heat sink. This is because silicon (in the silicon interposer) and the organic laminate substrate 85 are not good heat conductors. Using the bi-wafer approach (FIG. 7), heat can now be dissipated both through the backside of the high-power logic dies and also through the diamond in the bi-wafer enabled active ICs and interposers. This can dramatically enhances the dissipation of heat from the hot spots in high-power chips during their operation.

In FIGS. 6A, 6B and 7, ICs enabled by full-sized 300 mm bi-wafers (FIGS. 2 and 5) can have the diamond layers on their top or bottom sides according to needs. Take the 3D IC in FIG. 6B for instance, the diamond layer of the processor could also be located directly under DRAM. The same can be said on bi-wafer enabled active ICs and the interposer in FIG. 7.

Composite semiconductor wafers or composite semiconductor chips disclosed herein can be deployed to the fabrication of advanced ICs and practically all types of advanced SiPs comprising 2.5D IC, 3D IC, fan-out, silicon photonics, chiplets-in-SiP and their combinations thereof. Furthermore, in FIG. 7, the control die 711, the high-bandwidth DRAM 712, the GPU 73, the CPU 74 could be the composite semiconductor chip described in FIGS. 2, and the interposer 75 could be the composite semiconductor chip described in FIG. 5. The composite semiconductor chip described in FIG. 2 or FIG. 5 at least integrates with two heterogeneous layers, and the 2.5D IC of 3D IC described in FIG. 7 integrates more heterogeneous chips, thus the present invention just discloses a heterogeneous integration semiconductor structure/system to expedite heat dissipation.

In addition to silicon-diamond bi-wafers, the approaches shown in FIGS. 2 and 5 can also be applied to many other materials which can be bonded through low-temperature direct bonding. They include (but not limited to) Si-SiO₂, GaN-GaN, SiC-GaN, SiC-SiC and InP (indium phosphide)-InP. The invention disclosed herein that invokes advanced packaging (e.g., 300 mm fan-out processing and direct bonding) and novel processes and materials can be applied to create a plethora of large (300 mm and beyond using, for instance, panel-level processing) bi-wafers that consist of diamond (or other high thermal conductivity materials) or are made up of the aforementioned materials that can be direct bonded way ahead of their respective wafer diameter and bi-wafer diameter growth curves for dramatically enhanced productivity and product lives.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded with the broadest interpretation so as to encompass all such modifications and similar arrangements and procedures.

What is claimed is:

1. A method to form a composite semiconductor wafer with a first dimension, comprising:
preparing a plurality of composite blocks, wherein each composite block comprises a thermal dissipation layer and a semiconductor layer, a dimension of each composite block is smaller than the first dimension, and a thermal conductivity of the thermal dissipation layer is greater than that of the semiconductor layer; and
merging the plurality of composite blocks to form the composite semiconductor wafer with the first dimension.

2. The method in claim 1, wherein the process of preparing the plurality of composite blocks comprises:
bonding a set of thermal dissipation layers on a semiconductor substrate; and
dicing the semiconductor substrate with the set of thermal dissipation layers to form the plurality of composite blocks.

3. The method in claim 2, before the step of dicing, further comprising:
depositing a filling material over the semiconductor substrate bonded with the set of thermal dissipation layer; and
planarizing the filling material to reveal the set of thermal dissipation layers.

4. The method in claim 3, wherein the semiconductor substrate is a silicon substrate, the thermal dissipation layer of each composite block is a diamond layer, the semiconductor layer of each composite block is a silicon layer, and the filling material is made of silicon dioxide.

5. The method in claim 2, wherein the process of bonding the set of thermal dissipation layers on the semiconductor substrate comprises:
attaching the set of thermal dissipation layer to a temporary carrier;
bonding the set of thermal dissipation layers on the temporary carrier to the semiconductor substrate, such that the set of thermal dissipation layer are bonded on the semiconductor substrate; and
removing the temporary carrier.

6. The method in claim 5, wherein each thermal dissipation layer is separate from one adjacent thermal dissipation layer at least by a dicing street distance after the set of thermal dissipation layers are attached to the temporary carrier.

7. The method in claim 1, wherein the process of merging comprises:
attaching the plurality of composite blocks to a temporary substrate;
depositing a molding material over the plurality of composite blocks and the temporary substrate;
planarizing the molding material to reveal the plurality of composite blocks; and
removing the temporary substrate to form the composite semiconductor wafer with the first dimension.

8. The method in claim 1, wherein the first dimension is approximate to 300 mm.

9. The method in claim 1, wherein the process of preparing the plurality of composite blocks comprises:
preparing a semiconductor substrate with a thermal dissipation film thereon; and
dicing the semiconductor substrate with the thermal dissipation film to form the plurality of composite blocks.

10. The method in claim 9, wherein the process of preparing the semiconductor substrate with the thermal dissipation film thereon comprises:
preparing the semiconductor substrate;
forming the thermal dissipation film on the semiconductor substrate;
and depositing a sacrificial layer over the thermal dissipation film and planarizing the sacrificial layer to form the semiconductor substrate with the thermal dissipation film.

11. The method in claim 10, wherein the thermal dissipation film is a diamond film and the sacrificial layer is made of SiO₂.

12. The method in claim 9, wherein the process of preparing the semiconductor substrate with the thermal dissipation film thereon comprises:
attaching the semiconductor substrate to a temporary carrier;
depositing the thermal dissipation film over the semiconductor substrate;
depositing a sacrificial layer on the thermal dissipation film and planarizing the sacrificial layer; and
removing the temporary carrier to form the semiconductor substrate with the thermal dissipation film.

13. The method in claim 1, wherein the process of preparing the plurality of composite blocks comprises:
5 depositing a thermal dissipation film over a set of semiconductor chips to form a semiconductor substrate with the thermal dissipation film;
and dicing the semiconductor substrate with the thermal dissipation film to form the plurality of composite blocks.

14. The method in claim 13, wherein the process of depositing the thermal dissipation film over the set of semiconductor chips comprises:
preparing the set of semiconductor chips;
forming the thermal dissipation film on the set of semiconductor chips; and
depositing a sacrificial layer over the thermal dissipation film and planarizing the sacrificial layer to form the semiconductor substrate with the thermal dissipation film.

15. The method in claim 14, wherein the thermal dissipation film is a diamond film and sacrificial layer is made of SiO₂.

16. The method in claim 13, wherein the process of depositing the thermal dissipation film over the set of semiconductor chips comprises:
attaching the set of semiconductor chips to a temporary carrier;
forming the thermal dissipation film over the set of semiconductor chips;
depositing a sacrificial layer over the thermal dissipation film and planarizing the sacrificial layer; and
removing the temporary carrier to form the semiconductor substrate with the thermal dissipation film.

17. A method to form a composite semiconductor wafer with a first dimension, comprising:
attaching a set of thermal dissipation layers to a temporary carrier;
bonding the set of thermal dissipation layers on the temporary carrier to a semiconductor substrate with the first dimension, such that the set of thermal dissipation layers are bonded to the semiconductor substrate; and
removing the temporary carrier to form the composite semiconductor wafer with the first dimension. (PS: “the composite” is required due to claim grammar)

18. The method in claim 17, wherein the first dimension is approximate to 300 mm.

19. The method in claim 17, further comprising:
depositing a filling material over the semiconductor substrate bonded with the set of thermal dissipation layers; and
planarizing the filling material to reveal the set of thermal dissipation layers.

20. The method in claim 19, wherein the semiconductor substrate is a Si substrate, the filling material is made of Si containing materials, and each thermal dissipation layer is made of diamond.

21. The method in claim 17, wherein each thermal dissipation layer is separate from one adjacent thermal dissipation layer at least by a dicing street distance after the set of thermal dissipation layers are attached to the temporary carrier.

22. A heterogeneous semiconductor structure, comprising:
a substrate; and
a composite semiconductor chip over the substrate; wherein the composite semiconductor chip includes a thermal dissipation side and a semiconductor side.

23. The heterogeneous semiconductor structure in claim 22, further comprising:
a heat spreader over the thermal dissipation side of the composite semiconductor chip; and
a heat sink over the heat spreader.

24. The heterogeneous semiconductor structure in claim 22, further comprising another semiconductor chip bonded to the semiconductor side of the composite semiconductor chip.

25. The heterogeneous semiconductor structure in claim 22, further comprising another composite semiconductor chip bonded to the composite semiconductor chip.

26. A heterogeneous semiconductor structure, comprising:
a substrate; and
a composite semiconductor chip over the substrate; wherein the composite semiconductor chip includes a thermal dissipation layer and a semiconductor layer, the thermal dissipation layer directly contacts to the semiconductor layer without any adhesive material between the thermal dissipation layer and the semiconductor layer.

27. The heterogeneous semiconductor structure in claim 26, further comprising another semiconductor chip electrically connected to the composite semiconductor chip, wherein the semiconductor layer of the composite semiconductor chip includes a first plurality of active circuits and the another semiconductor chip includes a second plurality of active circuits.

28. The heterogeneous semiconductor structure in claim 26, further comprising another composite semiconductor chip electrically connected to the composite semiconductor chip, wherein the another composite semiconductor chip comprises another thermal dissipation layer and another semiconductor layer bonded to the another thermal dissipation layer.

29. A heterogeneous semiconductor structure, comprising:
a substrate; and
a composite semiconductor chip over the substrate; wherein the composite semiconductor chip includes a thermal dissipation layer, a semiconductor layer, and a molding compound covering sidewalls of the thermal dissipation layer and the semiconductor layer.

30. The heterogeneous semiconductor structure in claim 29, further comprising another semiconductor chip electrically connected to the composite semiconductor chip, wherein the composite semiconductor chip includes a first plurality of through vias and the another semiconductor chip includes a plurality of active circuits.

31. The heterogeneous semiconductor structure in claim 29, further comprising another composite semiconductor chip electrically connected to the composite semiconductor chip, wherein the composite semiconductor chip includes a first plurality of through vias, the another composite semiconductor chip includes another thermal dissipation layer and another semiconductor layer, the another thermal dissipation layer directly contacts to the another semiconductor layer without any adhesive material between the another thermal dissipation layer and the another semiconductor layer.
